(19) United States
(12) Patent Application Publication
(10) Pub. No.: US 2025/0246586 A1
(43) Pub. Date: Jul. 31, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Ching-Chia CHEN, Taichung City (TW); Wen-Jung TSAI, Taichung City (TW); Ting-Yang CHOU, Taichung City (TW); Chia-Cheng CHEN, Taichung City (TW); Yu-Po WANG, Taichung City (TW)

(21) Appl. No.: 18/758,648

(22) Filed: Jun. 28, 2024

(30) Foreign Application Priority Data
Jan. 25, 2024 (TW) 113102992

(51) Int. Cl. H01L 25/16; H01L 23/48; H01L 23/498

(52) U.S. Cl. CPC H01L 25/167; H01L 23/481; H01L 23/49816

(57) ABSTRACT

An electronic package and a manufacturing method thereof are provided, in which a wiring structure electrically connected to a photonic structure is disposed on a surface of a part of the photonic structure, an electronic component is disposed on the wiring structure to be electrically connected to the wiring structure, and an optical element is disposed on a surface of another part of the photonic structure to be electrically connected to the photonic structure. Therefore, the photonic structure and the electronic component are placed relatively vertically on opposite sides of the wiring structure, thereby effectively reducing the layout area of the wiring structure to meet the demand for miniaturization.

### CROSS-REFERENCE TO RELATED APPLICATIONS

The present application is based upon and claims the right of priority to TW patent application Ser. No. 11/310,2992, filed Jan. 25, 2024, the disclosure of which is hereby incorporated by reference herein in its entirety for all purposes.

### BACKGROUND

### 1. Technical Field

The present disclosure relates to a semiconductor device, and more particularly, to an electronic package comprising an optoelectronic element and a manufacturing method thereof.

### 2. Description of Related Art

At present, the application of the fifth generation (5G) communication technology has been extended to the internet of things (IoT), industrial internet of things (IIoT), cloud, artificial intelligence (AI), autonomous cars and medical and other fields. Moreover, with the expansion of the application level, a very large amount of data will be generated in the process and need to be transmitted, calculated and stored efficiently. Therefore, in recent years, large-scale data centers and cloud servers have a large number of data transmission needs. The industry has begun to enter the field of optical communications, using “light” instead of “electricity” as the carrier of data transmission.

Optical communication can improve transmission capacity/efficiency/distance to increase data bandwidth and reduce unit energy consumption. Therefore, silicon photonic elements and their application products have begun to be valued again in terms of their existence value and research and development.

As shown in FIG. 1, a conventional semiconductor package 1 having optoelectronic elements is provided with a photonic chip 11 and an electronic chip 16 spaced apart in the horizontal direction on a substrate structure 10.

However, in the aforementioned semiconductor package 1, the photonic chip 11 and the electronic chip 16 are mainly placed in parallel on the substrate structure 10, thereby occupying a large surface area of the substrate structure 10, so that the layout of the semiconductor package 1 is difficult to be reduced and cannot meet the demand for miniaturization.

Therefore, how to overcome the above-mentioned problems of the prior art has become an urgent issue to be solved at present.

### SUMMARY

In view of the various deficiencies of the prior art, the present disclosure provides an electronic package, which comprises: a package module including a photonic structure; a wiring structure disposed on a surface of a part of the photonic structure and electrically connected to the photonic structure; an electronic component disposed on the wiring structure and electrically connected to the wiring structure; and an optical element disposed on a surface of another part of the photonic structure and electrically connected to the photonic structure.

The present disclosure also provides a method of manufacturing an electronic package, which comprises: providing a package module including a photonic structure; disposing a wiring structure on a surface of a part of the photonic structure, and electrically connecting the wiring structure to the photonic structure; disposing an electronic component on the wiring structure, such that the electronic component is electrically connected to the wiring structure; and disposing an optical element on a surface of another part of the photonic structure, so that the optical element is electrically connected to the photonic structure.

In the aforementioned electronic package and the manufacturing method thereof, the package module further includes an encapsulating layer embedding the photonic structure, and the wiring structure is further disposed on the encapsulating layer. For example, the package module further includes a plurality of conductive pillars embedded in the encapsulating layer and electrically connected to the wiring structure. Further, the package module further includes a circuit structure disposed on the encapsulating layer and electrically connected to the plurality of conductive pillars, such that the circuit structure and the wiring structure are respectively provided on two opposite surfaces of the encapsulating layer. Even, the photonic structure is electrically connected to the circuit structure.

In the aforementioned electronic package and the manufacturing method thereof, a metal resist layer is provided on part of the surface of the photonic structure, and after the metal resist layer is removed to expose part of the surface of the photonic structure, the optical element is disposed on the exposed surface of the photonic structure.

As can be seen from the above, in the electronic package and its manufacturing method of the present disclosure, a wiring structure is formed on a surface of a part of a photonic structure to provide an electronic component, so that the photonic structure and the electronic component are placed vertically on opposite sides of the wiring structure, thereby effectively reducing the layout area of the wiring structure. Therefore, compared with the prior art, the layout of the electronic package of the present disclosure can be effectively reduced to meet the demand for miniaturization.

### BRIEF DESCRIPTION OF THE DRAWINGS

FIG. 1 is a schematic cross-sectional view of a conventional semiconductor package.

FIG. 2A to FIG. 2F are schematic cross-sectional views illustrating a manufacturing method of an electronic package according to the present disclosure.

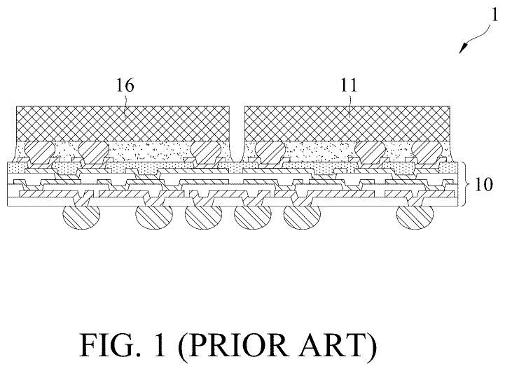

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

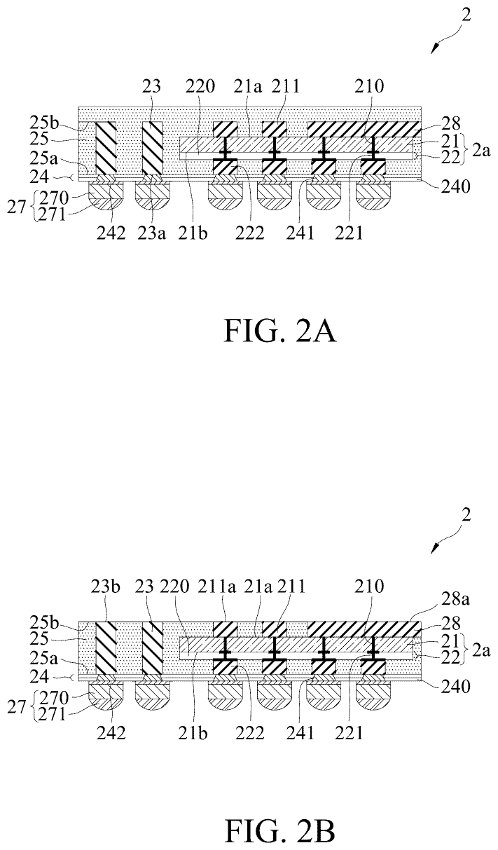

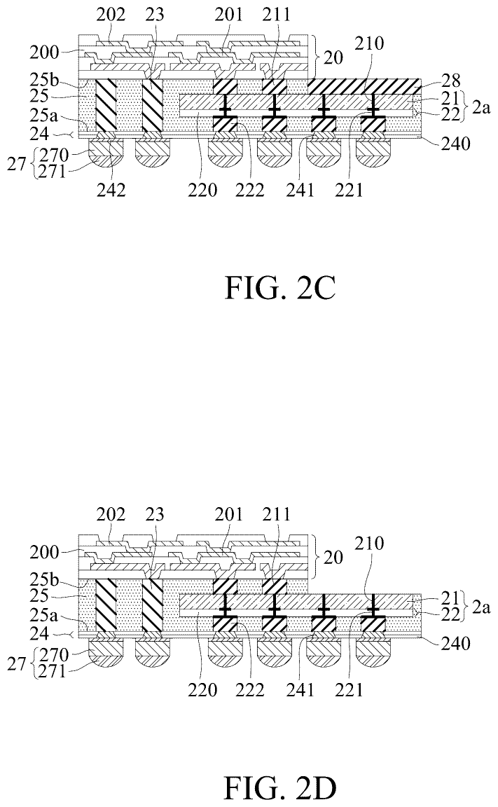

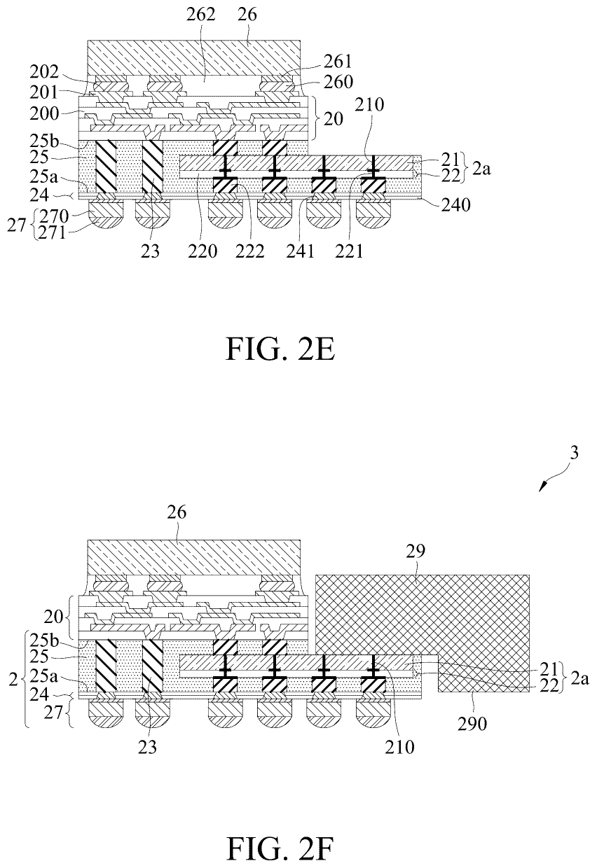

FIG. 2A to FIG. 2F are schematic cross-sectional views illustrating a manufacturing method of an electronic package 3 according to the present disclosure.

As shown in FIG. 2A, a package module 2 is provided, which includes a photonic structure 2a, an encapsulating layer 25, a conductive pillar 23 and a circuit structure 24.

The photonic structure 2a is in the form of a photonic integrated circuit (PIC), which includes a semiconductor substrate as a photonic body 21 and a circuit portion 22 bonded to the photonic body 21, wherein the photonic body 21 has a plurality of conductive through vias 210 formed inside it.

In one embodiment, the photonic structure 2a has a first side 21a and a second side 21b opposing to each other, and a plurality of conductive bumps 211, 222 electrically connected to the conductive through vias 210 and/or the circuit portion 22 can be formed on the first side 21a and/or the second side 21b as required. It should be understood that in the photonic structure 2a, the side of the photonic body 21 can be used as the first side 21a or the second side 21b, and the side of the circuit portion 22 can be used as the other side according to requirements, and the present disclosure is not limited to as such.

Furthermore, the conductive through vias 210 are conductive silicon vias (TSV), and the conductive bumps 211, 222 are metal bumps such as copper bumps, wherein the circuit portion 22 includes at least one insulating layer 220 and a conductive trace 221 bonded to the insulating layer 220, such that the conductive trace 221 is electrically connected to one of the conductive through vias 210 and one of the conductive bumps 222.

In addition, at least one metal resist layer 28 can be formed on the photonic body 21 as required to cover some of the conductive through vias 210.

The conductive pillar 23 has at least one or a plurality of them, which are embedded in the encapsulating layer 25 and spaced apart from the photonic structure 2a, and the conductive pillar 23 is made of metal such as copper or solder material.

The encapsulating layer 25 covers the photonic structure 2a and the conductive pillar 23, and the encapsulating layer 25 has a first surface 25a and a second surface 25b opposing to each other, such that one end surface 23a of the conductive pillar 23 and the conductive bumps 222 of the circuit portion 22 are flush with the first surface 25a of the encapsulating layer.

In one embodiment, the encapsulating layer 25 is an insulating material, such as polyimide (PI), dry film, encapsulating colloid such as epoxy resin or molding compound. For example, the encapsulating layer 25 can be produced by selecting liquid compound, injection, lamination or compression molding.

The circuit structure 24 is provided on the first surface 25a of the encapsulating layer 25, such that the circuit structure 24 is electrically connected to the plurality of conductive pillars 23 and the plurality of conductive bumps 222 on the circuit portion 22

In one embodiment, the circuit structure 24 includes at least one dielectric layer 240 and a circuit layer 241, such as a redistribution layer (RDL) specification, disposed on the dielectric layer 240, such that the circuit layer 241 is electrically connected to the plurality of conductive pillars 23 and the plurality of conductive bumps 222 on the circuit portion 22, wherein the outermost dielectric layer 240 can be used as a solder mask, and the outermost circuit layer 241 exposes the solder mask to serve as electrical contact pads 242 to be bonded to a plurality of conductive elements 27. For example, each of the conductive elements 27 includes a metal bump 270 such as copper and a solder material 271 formed on the metal bump 270.

Preferably, an under-bump metallization (UBM) layer (not shown) can be formed on the electrical contact pad 242 to facilitate bonding with the metal bump 270.

Furthermore, the material for forming the circuit layer 241 is copper, and the material for forming the dielectric layer 240 is polybenzoxazole (PBO), polyimide (PI), prepreg (PP), or solder-resist materials such as solder mask, ink, and the like.

As shown in FIG. 2B, part of the material of the second surface 25b of the encapsulating layer 25 is removed to expose the conductive pillars 23, the metal resist layer 28 and the conductive bumps 211 on the photonic body 21.

In one embodiment, a leveling process can be used to make the second surface 25b of the encapsulating layer 25 flush with the other end surface 23b of the conductive pillar 23, a surface 28a of the metal resist layer 28 and end surfaces 211a of the conductive bumps 211, such that the end surface 23b of the conductive pillar 23, the surface 28a of the metal resist layer 28 and the end surfaces 211a of the conductive bumps 211 expose from the second surface 25b of the encapsulating layer 25. For example, the leveling process removes part of the material of the encapsulating layer 25, part of the material of the conductive pillar 23, part of the material of the conductive bump 211 and part of the material of the metal resist layer 28 via grinding.

As shown in FIG. 2C, a wiring structure 20 is formed on part of the second surface 25b of the encapsulating layer 25, such that the wiring structure 20 is electrically connected to the conductive pillars 23 and the conductive bumps 211 on the photonic body 21, wherein the wiring structure 20 is exposed from the metal resist layer 28 so as to be not electrically connected to the metal resist layer 28.

The wiring structure 20 includes at least one insulating layer 200 and a wiring layer 201 bonded to the insulating layer 200, such that the wiring layer 201 is electrically connected to the conductive pillar 23 and the conductive bumps 211 on the photonic body 21.

In one embodiment, the material for forming the insulating layer 200 is such as polybenzoxazole (PBO), polyimide (PI), or prepreg (PP) or other dielectric materials, and the wiring layer 201 can be formed using a redistribution layer (RDL) process. For example, the outermost wiring layer 201 has a plurality of electrical contact pads 202.

As shown in FIG. 2D, the metal resist layer 28 is removed to expose the conductive through vias 210 of the photonic body 21.

As shown in FIG. 2E, an electronic component 26 is disposed on the wiring structure 20, so that the electronic component 26 is electrically connected to the wiring structure 20.

The electronic component 26 is an active element, a passive element or a combination of the active element and the passive element, wherein the active element is, for example, a semiconductor chip, and the passive element is, for example, a resistor, a capacitor, and an inductor.

In one embodiment, the electronic component 26 is, for example, an electronic IC (EIC) component.

Furthermore, the electronic component 26 can be electrically connected to the electrical contact pads 202 via a plurality of conductive bumps 261 and/or solder material 260 in a flip-chip manner; alternatively, the electronic component 26 can also be electrically connected to the electrical contact pads 202 via a plurality of bonding wires (not shown) in a wire bonding manner; even, the electronic component 26 may be directly contacted to the electrical contact pads 202. However, the manner in which the electronic component 26 is electrically connected to the wiring layer 201 is not limited to the above.

Preferably, an under bump metallurgy (UBM) layer (not shown) can be formed on the electrical contact pad 202 to facilitate bonding with the solder material 260 or the conductive bump 261.

In addition, an underfill 262 can be formed between the electronic component 26 and the wiring structure 20 to cover the conductive bumps 261 and the solder material 260.

As shown in FIG. 2F, at least one optical element 29 is disposed on the photonic body 21 of the photonic structure 2a, such that the optical element 29 is electrically connected to the conductive through vias 210.

In one embodiment, the optical element 29 protrudes from the side of the photonic structure 2a and the encapsulating layer 25, and extends a functional section 290 to the side of the conductive element 27 to form an L-shaped structure.

Furthermore, some of the conductive through vias 210 of the photonic structure 2a are electrically connected to the electronic component 26 via the wiring structure 20, and some of the conductive through vias 210 of the photonic structure 2a are electrically connected to the optical element 29.

Therefore, in the electronic package 3 of the present disclosure, the wiring structure 20 is formed on a partial area of the photonic structure 2a to provide the electronic component 26, so that the photonic structure 2a and the electronic component 26 are placed vertically on opposite sides of the wiring structure 20, thereby effectively reducing the layout area of the wiring structure 20. Therefore, compared with the prior art, the layout of the electronic package 3 of the present disclosure can be effectively reduced to meet the demand for miniaturization. In addition, the present disclosure exposes part of the photonic structure 2a, allowing direct connection to the optical element 29, resulting in fewer interfaces, reducing alignment challenges, and eliminating the need to change the traditional chip structure, resulting in high transmission efficiency.

The present disclosure provides an electronic package 3, which comprises: a package module 2 including a photonic structure 2a, a wiring structure 20, at least one electronic component 26 and at least one optical element 29.

The wiring structure 20 is disposed on a part of the surface of the photonic structure 2a and is electrically connected to the photonic structure 2a.

The electronic component 26 is disposed on the wiring structure 20 to be electrically connected to the wiring structure 20.

The optical element 29 is disposed on the surface of another part of the photonic structure 2a and is electrically connected to the photonic structure 20.

In one embodiment, the package module 2 further comprises an encapsulating layer 25 embedding the photonic structure 2a, and the wiring structure 20 is disposed on the encapsulating layer 25.

In one embodiment, the package module 2 further comprises at least one conductive pillar 23 embedded in the encapsulating layer 25 and electrically connected to the wiring structure 20.

In one embodiment, the package module 2 further comprises at least one circuit structure 24 disposed on the encapsulating layer 25 and electrically connected to the conductive pillar 23, such that the circuit structure 24 and the wiring structure 20 are respectively provided on two opposite surfaces of the encapsulating layer 25.

In one embodiment, the photonic structure 2a is electrically connected to the circuit structure 24.

To sum up, in the electronic package and its manufacturing method of the present disclosure, the photonic structure and the electronic component are placed relatively vertically on opposite sides of the wiring structure, thereby effectively reducing the layout area of the wiring structure. Therefore, the layout of the electronic package of the present disclosure can be effectively reduced to meet the demand for miniaturization.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a package module, including a photonic structure;
a wiring structure, disposed on a surface of a part of the photonic structure and electrically connected to the photonic structure;
an electronic component, disposed on the wiring structure and electrically connected to the wiring structure; and
an optical element, disposed on a surface of another part of the photonic structure and electrically connected to the photonic structure.

2. The electronic package of claim 1, wherein the package module further includes an encapsulating layer embedding the photonic structure, and the wiring structure is further disposed on the encapsulating layer.

3. The electronic package of claim 2, wherein the package module further includes a plurality of conductive pillars embedded in the encapsulating layer and electrically connected to the wiring structure.

4. The electronic package of claim 3, wherein the package module further includes a circuit structure disposed on the encapsulating layer and electrically connected to the plurality of conductive pillars, such that the circuit structure and the wiring structure are respectively provided on two opposite surfaces of the encapsulating layer.

5. The electronic package of claim 4, wherein the photonic structure is electrically connected to the circuit structure.

6. A method of manufacturing an electronic package, comprising:
providing a package module including a photonic structure;
disposing a wiring structure on a surface of a part of the photonic structure, and electrically connecting the wiring structure to the photonic structure;
disposing an electronic component on the wiring structure, such that the electronic component is electrically connected to the wiring structure; and
disposing an optical element on a surface of another part of the photonic structure, so that the optical element is electrically connected to the photonic structure.

7. The method of claim 6, wherein the package module further includes an encapsulating layer embedding the photonic structure, and the wiring structure is further disposed on the encapsulating layer.

8. The method of claim 7, wherein the package module further includes a plurality of conductive pillars embedded in the encapsulating layer and electrically connected to the wiring structure.

9. The method of claim 8, wherein the package module further includes a circuit structure disposed on the encapsulating layer and electrically connected to the plurality of conductive pillars, such that the circuit structure and the wiring structure are respectively provided on two opposite surfaces of the encapsulating layer.

10. The method of claim 8, wherein a metal resist layer is provided on part of the surface of the photonic structure, and after the metal resist layer is removed to expose part of the surface of the photonic structure, the optical element is disposed on the exposed surface of the photonic structure.
